(19) United States
(12) Patent Application Publication
(10) Pub. No.: US 2022/0005407 A1
(43) Pub. Date: Jan. 6, 2022

(54) DISPLAY PANEL, DISPLAY SCREEN, AND ELECTRONIC DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Shang ZHOU, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 16/968,889

(22) PCT Filed: Jul. 21, 2020
(86) PCT No.: PCT/CN2020/103285

§ 371 Date: Aug. 11, 2020

(30) Foreign Application Priority Data
Jul. 1, 2020 (CN) 202010622889.2

(51) Int. Cl. G09G 3/3208; H01L 27/32

(52) U.S. Cl. CPC G09G 3/3208; G09G 2330/028; G09G 2300/0439; H01L 27/3276

(57) ABSTRACT

The present invention provides a display panel, a display screen, and an electronic device. The display panel includes a non-shared pixel array including a plurality of non-shared pixel columns and a plurality of non-shared pixel rows, a shared pixel array including a plurality of shared pixel columns and a plurality of shared pixel rows, and a plurality of data lines, wherein the non-shared pixel row and the shared pixel column adjacent to the non-shared pixel row correspond to one data line.

### FIELD OF INVENTION

The present disclosure relates to the field of display technology, and more particularly, to a display panel, a display screen, and an electronic device.

### BACKGROUND OF INVENTION

A structure of small and medium-sized organic light-emitting diode display devices is mainly composed of a driving backplane and pixels (organic light-emitting diodes) with a specific arrangement structure. A brightness of each organic light-emitting diode is individually controlled by an output current of a driving circuit unit, and a pixel array consisting of organic light-emitting diodes with different light-emitting colors is controlled by a corresponding drive circuit, to finally realize an output of images.

However, in current Pentile arrangement of pixels, each row of pixels corresponds to a data line, that is, a greater number of data lines results in a greater width of a region where fan-out lines between a display region and a driving chip, which results in a larger borders of a display panel.

### SUMMARY OF INVENTION

An embodiment of the present disclosure provides a display penal, a display screen, and an electronic device, which can reduce a frame of the display panel.

The embodiment of the present disclosure provides a display panel comprising a non-shared pixel array consisting of a plurality of non-shared pixels, wherein the non-shared pixel array comprises a plurality of non-shared pixel columns and a plurality of non-shared pixel rows, a shared pixel array consisting of a plurality of shared pixels, wherein the shared pixel array comprises a plurality of shared pixel columns and a plurality of shared pixel rows, the shared pixel columns are disposed between two adjacent non-shared pixel columns, and the shared pixel rows are disposed between two adjacent non-shared pixel rows, a plurality of data lines, wherein the non-shared pixel row and the shared pixel column adjacent to the non-shared pixel row correspond to one data line, and a plurality of scanning lines, wherein the non-shared pixel column and the shared pixel column respectively correspond to one scanning line.

The present disclosure further provides a display screen comprising the above display panel.

The present disclosure further provides an electronic device comprising the above display screen.

The display panel, the display screen, and the electronic device the embodiment of the present disclosure comprises the non-shared pixel array consisting of the plurality of non-shared pixels, wherein the non-shared pixel array comprises the plurality of non-shared pixel columns and the plurality of non-shared pixel rows, the shared pixel array consisting of the plurality of shared pixels, wherein the shared pixel array comprises the plurality of shared pixel columns and the plurality of shared pixel rows, the shared pixel columns are disposed between the two adjacent non-shared pixel columns, and the shared pixel rows are disposed between the two adjacent non-shared pixel rows, the plurality of data lines, wherein the non-shared pixel row and the shared pixel column adjacent to the non-shared pixel row correspond to one data line, and the plurality of scanning lines, wherein the non-shared pixel column and the shared pixel column respectively correspond to one scanning line. Since the number of data lines is reduced, a width of a region where fan-out lines are located is reduced, thereby reducing the frame of the display panel.

### DESCRIPTION OF DRAWINGS

In order to illustrate technical solutions of the embodiments more clearly, drawings used in a description of the embodiments will be briefly described as below. Obviously, the drawings described as below are just some embodiments of the present disclosure. For those of ordinary skill in the art, under a premise of no creative labor, other drawings can also be obtained according to these drawings.

FIG. 1 is a top view of a current display panel.

FIG. 2 is a top view of a display panel provided by an embodiment of the present disclosure.

FIG. 3 is a top view of pixels in the display panel provided by another embodiment of the present disclosure.

FIG. 4 is a structural diagram of a display screen provided by one embodiment of the present disclosure.

FIG. 5 is a structural diagram of an electronic device provided by one embodiment of the present disclosure.

### DETAILED DESCRIPTION OF PREFERRED EMBODIMENTS

The technical solutions in the embodiments of the present disclosure will be clearly and completely described below in conjunction with accompanying drawings in the embodiments of the present disclosure. Obviously, the embodiments described are merely a part of the present disclosure, rather than all the embodiments. All other embodiments obtained by the person having ordinary skill in the art based on embodiments of the disclosure, without making creative efforts, are within the scope of the present disclosure.

In descriptions of the present disclosure, it should be noted that, orientations or position relationships indicated by the terms, such as “center”, “longitudinal”, “transverse”, “length”, “width”, “thickness”, “upper”, “lower”, “front”, “back”, “left”, “right”, “vertical”, “horizontal”, “top”, “bottom”, “inside”, “outside”, “clockwise”, “counterclockwise”, etc. are based on the orientations or position relationships shown in the drawings. These are only convenience for describing the present disclosure and simplifying the descriptions, and does not indicate or imply that the device or element must have a specific orientation, a structure and an operation in the specific orientation, so it cannot be understood as a limitation on the present disclosure. In addition, the terms “first” and “second” are used for describing purposes only, and cannot be understood as indicating or implying relative importance or implicitly indicating the number of technical features indicated. Thus, the features defined as “first” and “second” may explicitly or implicitly include one or more of the features. In the descriptions of the present disclosure, the meaning of “plurality” is two or more, unless it is specifically defined otherwise.

In the present disclosure, the terms “mounting”, “connected”, “fixed” and the like should be broadly understood unless expressly stated or limited otherwise. For example, it may be fixed connected, removably connected, or integrated; it may be mechanically connected, or an electrically connected; it may be directly connected, or indirectly connected by an intermediary; it may be a connection between two elements or an interaction between two elements. For those skilled in the art, the specific meanings of the above terms in the present disclosure may be understood based on specific situations.

In the present disclosure, unless explicitly stated and defined otherwise, the first feature may be “above” or “below” the second feature and may include direct contact between the first and second features. It may also include that the first and second features are not in direct contact but are contacted by another feature between them. Moreover, the first feature is “above” the second feature, including the first feature directly above and obliquely above the second feature, or merely indicates that the first feature is higher in level than the second feature. The first feature is “below” the second feature, including the first feature is directly below and obliquely below the second feature, or only indicates that the first feature is less horizontal than the second feature.

The following disclosure provides many different embodiments or examples for achieving different structures of the present disclosure. To simplify the present disclosure, components and settings of specific examples are described below. They are only examples and are not intended to limit the present disclosure. In addition, the present disclosure may repeat reference numbers and/or reference letters in different examples, this repetition is for the purpose of simplicity and clarity, and does not itself indicate the relationship between various embodiments and/or settings discussed. In addition, the present disclosure provides examples of various specific processes and materials, but those of ordinary skill in the art may be aware of the present disclosure of other processes and/or the use of other materials.

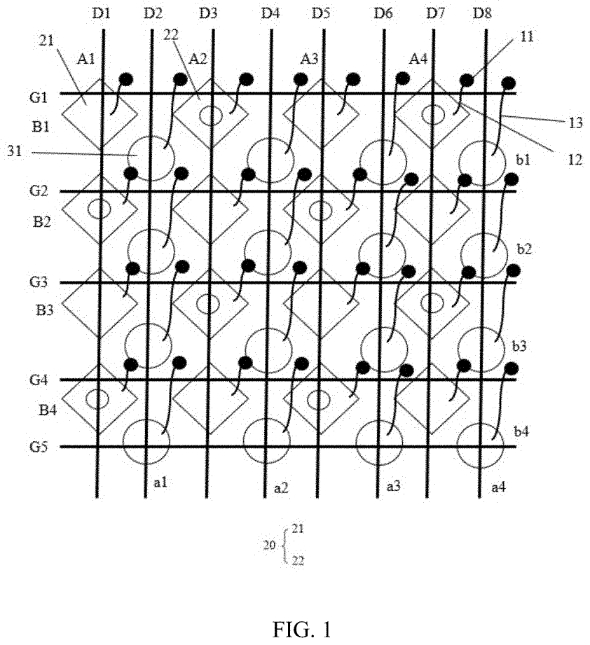

As shown in FIG. 1, a current display panel comprises a non-shared pixel array consisting of a plurality of non-shared pixels 20, a shared pixel array consisting of a plurality of shared pixels 31, a plurality of data lines D1 to D8, and a plurality of scanning lines G1 to G5.

The non-shared pixel array comprises a plurality of non-shared pixel columns B1 to B4 and a plurality of non-shared pixel rows A1 to A4.

The shared pixel array comprises a plurality of shared pixel columns b1 to b4 and a plurality of shared pixel rows a1 to a4. The shared pixel columns are disposed between two adjacent non-shared pixel columns, and the shared pixel rows are disposed between two adjacent non-shared pixel rows. Each non-shared pixel row and each shared pixel row correspond to one data line, and the non-shared pixel column and the shared pixel column correspond to one scanning line.

Moreover, each non-shared sub-pixel in the non-shared pixel column and each shared sub-pixel in the shared pixel column correspond to a main power signal access point 11, the main power signal access points are located in a same column. The non-shared sub-pixel is connected to an anode of the non-shared sub-pixel by a first connecting line 12, and the shared sub-pixel 31 is connected to an anode of the shared sub-pixel by a second connecting line 13.

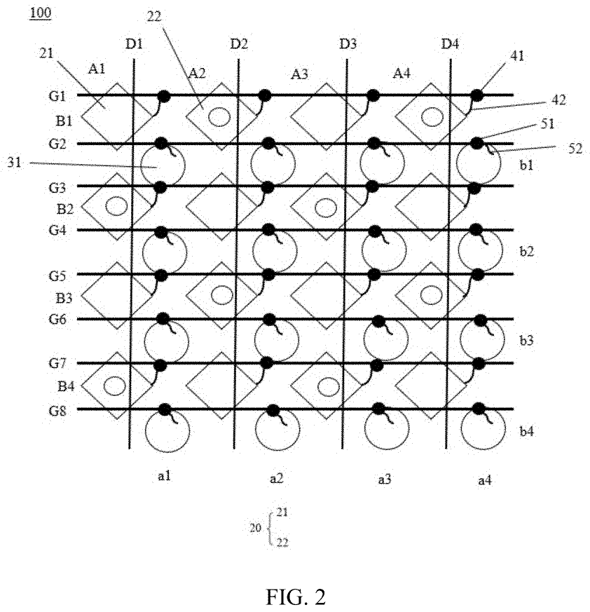

Refer to FIG. 2, FIG. 2 is a top view of a display panel provided by an embodiment of the present disclosure.

As shown in FIG. 2, the display panel 100 comprises the non-shared pixel array (not shown) consisting of the plurality of non-shared pixels 20, the shared pixel array consisting of the plurality of shared pixels 31, a plurality of data lines D1 to D4, and a plurality of scanning lines G1 to G8. Furthermore, it should be understood that the number of data lines and the number of scanning lines are not limited herein.

The non-shared pixel array comprises the plurality of non-shared pixel columns B1 to B4 and the plurality of non-shared pixel rows A1 to A4. Furthermore, the number of non-shared pixel columns and the number of non-shared pixel rows are not limited herein.

The shared pixel array comprises the plurality of shared pixel columns 131 to b4 and the plurality of shared pixel rows a1 to a4, the shared pixel columns are disposed between the two adjacent non-shared pixel columns, and the shared pixel rows are disposed between the two adjacent non-shared pixel rows; for example, a1 is located between A1 and A2, 131 is located between B1 and B2, and the others are similar to thereof. Furthermore, the number of shared pixel columns and the number of shared pixel rows are not limited herein.

The non-shared pixel row and the shared pixel column adjacent to the non-shared pixel row correspond to one data line; for example, a1 and a2 share one data line, and the other pixel rows are similar to thereof. It should be understood that the shared pixels 31 are connected to corresponding data lines. (nor shown).

The non-shared pixel column and the shared pixel column respectively correspond to one scanning line, that is, each non-shared pixel column and each shared pixel column correspond to one scanning line; for example, the non-shared pixel columns B1, b1, B2, b2, B3, b3, B4, and b4 respectively correspond to one of the scanning lines G1 to G8.

In one embodiment, in order to reduce a length of the connecting line with the data line to reduce attenuation of data signals. The data line is located between the corresponding non-shared pixel row and the shared pixel row adjacent to the non-shared pixel row. For example, take a first data line as an example, D1 is located between A1 and a1. Preferably, the data line is located in a middle position between the non-shared pixel row and the shared pixel row adjacent to the non-shared pixel row. D1 is located in a middle position between A1 and a1. It should be understood that the non-shared pixel row and the shared pixel row adjacent to the non-shared pixel row are arranged at intervals.

In one embodiment, in order to reduce a width of a region where fan-out lines are located, a total number of the data lines is equal to a total number of the non-shared pixel rows, and a total number of the non-shared pixel rows is greater than or equal to a total number of the shared pixel rows. In one embodiment, the total number of the data lines is 4, the total number of the non-shared pixel rows is 4, and the total number of the shared pixel rows is 4.

In one embodiment, in order to improve accuracy of access of the data signals, a total number of the scanning lines is a sum of a total number of the non-shared pixel columns and a total number of the shared pixel columns. For example, in one embodiment, the total number of the scanning lines is 8, the total number of the non-shared pixel columns is 4, and the total number of the shared pixel columns is 4.

In one embodiment, the non-shared pixel 20 comprises two non-shared sub-pixels 21 and 22, each non-shared sub-pixel 21 and 22 in the non-shared pixel column respectively corresponds to a main power signal access point 41, a plurality of the main power signal access points 41 are located in a same column, and the main power signal access points 41 are used for receiving a first power voltage. For example, the first power voltage is a voltage connected to an anode of an organic light emitting diode.

In one embodiment, each shared sub-pixel 31 in the shared pixel column corresponds to a secondary power signal access point 51, a plurality of the secondary power signal access points 51 are located in a same column, and the secondary power signal access points 51 are used for receiving a second power voltage.

In one embodiment, the main power signal access point 41 is connected to an anode of the non-shared sub-pixel by a first connecting line 42, and the secondary power signal access point 51 is connected to an anode of the shared sub-pixel by a second connecting line 52.

In one embodiment, the non-shared sub-pixels 21 and 22 may respectively be a red sub-pixel and a blue sub-pixel, and the shared pixel 31 may be a green pixel. Moreover, it should be understood that FIG. 2 only is an example, which does not limit the present disclosure.

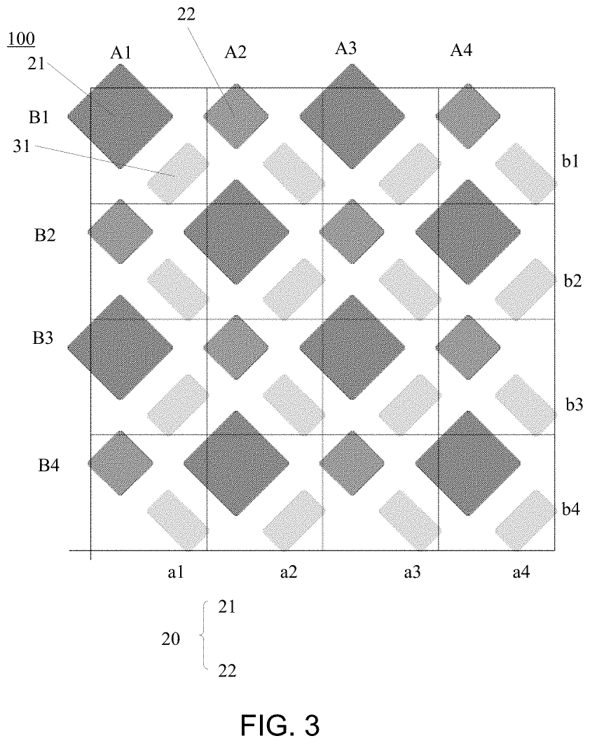

It should be understood that the display panel of the present embodiment may be an organic light emitting diode display panel, and a technical solution of the present embodiment is not limited to a pixel structure shown in FIG. 2. In other embodiments, as shown in FIG. 3, the same applies when a shape of the pixel is a rhombus, that is, the specific shape of the pixel does not limit the present disclosure, and the shape of the pixel can also be rectangular, circular, elliptical, etc.

Since the number of data lines is reduced, the width of the region where fan-out lines are located is reduced, thereby reducing the frame of the display panel.

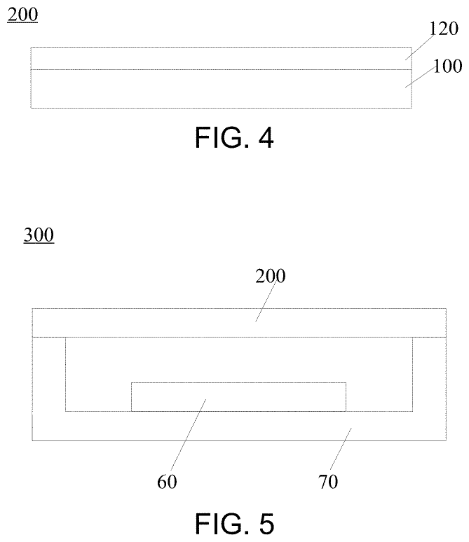

As shown in FIG. 4, the present embodiment further provides a display screen 200 comprising anyone of the above display panel 100, and the display screen further comprises a touch control layer 120. In one embodiment, the touch control layer 120 can be disposed above the display panel 100, but a setting method of the touch layer 120 is not limited herein.

Refer to FIG. 5, FIG. 5 is a structural diagram of an electronic device provided by one embodiment of the present disclosure. The electronic device can comprise the display screen 200, a control circuit 60, and a case 70. It should be noted that the electronic device 300 shown in FIG. 5 is not limited to the above content, it may also comprise other devices, such as a camera, an antenna structure, a pattern unlocking module, etc.

Wherein, the display screen 200 is disposed on the case.

In some embodiments, the display screen 200 can be fixed to the case 70, and the display screen 200 and the case 70 form a closed space to accommodate the control circuit 60 and other devices.

In some embodiments, the case 70 may be made of a flexible material, such as a plastic case or a silicone case, etc.

Wherein, the control circuit 60 is installed in the case 70, and the control circuit 60 can be a main board of the electronic device 300. The control circuit 60 can be integrated with one, two, or more of functional components such as battery, antenna structure, microphone, speaker, earphone interface, universal serial bus interface, camera, distance sensor, ambient light sensor, receiver, and processor.

Wherein, the display screen 200 is installed in the case 70, while the display screen 200 is electrically connected to the control circuit 60 to form a display surface of the electronic device 300. The display screen 200 may comprise a display region and a non-display region, the display region can be configured to display images of the electronic device 300 or for users to perform touch control, and the non-display region can be configured to set various functional components.

The electronic device comprises, but is not limited to, mobile phones, tablet computers, computer monitors, game consoles, televisions, wearable devices, and other household appliances or household appliances with display functions, etc.

The display panel, the display screen, and the electronic device the embodiment of the present disclosure comprises the non-shared pixel array consisting of the plurality of non-shared pixels, wherein the non-shared pixel array comprises the plurality of non-shared pixel columns and the plurality of non-shared pixel rows, the shared pixel array consisting of the plurality of shared pixels, wherein the shared pixel array comprises the plurality of shared pixel columns and the plurality of shared pixel rows, the shared pixel columns are disposed between the two adjacent non-shared pixel columns, and the shared pixel rows are disposed between the two adjacent non-shared pixel rows, the plurality of data lines, wherein the non-shared pixel row and the shared pixel column adjacent to the non-shared pixel row correspond to one data line, and the plurality of scanning lines, wherein the non-shared pixel column and the shared pixel column respectively correspond to one scanning line. Since the number of data lines is reduced, a width of a region where fan-out lines are located is reduced, thereby reducing the frame of the display panel.

The display panel, display screen, and electronic device provided by the embodiments of the present disclosure are described in detail above. Specific examples are used in the present disclosure to illustrate the principles and embodiments of the present disclosure. The description of the above embodiments is only used to help understand the present disclosure. At the same time, for those skilled in the art, according to ideas of the present disclosure, there will be changes in the specific embodiments and a scope of the present disclosure. In summary, the content of the specification should not be construed as a limitation to the present disclosure.

1. A display panel, comprising:
a non-shared pixel array consisting of a plurality of non-shared pixels, wherein the non-shared pixel array comprises a plurality of non-shared pixel columns and a plurality of non-shared pixel rows;
a shared pixel array consisting of a plurality of shared pixels, wherein the shared pixel array comprises a plurality of shared pixel columns and a plurality of shared pixel rows, the shared pixel columns are disposed between two adjacent non-shared pixel columns, and the shared pixel rows are disposed between two adjacent non-shared pixel rows;
a plurality of data lines, wherein the non-shared pixel row and the shared pixel column adjacent to the non-shared pixel row correspond to one data line; and
a plurality of scanning lines, wherein the non-shared pixel column and the shared pixel column respectively correspond to one scanning line;
wherein the non-shared pixel comprises two non-shared sub-pixels, each non-shared sub-pixel in the non-shared pixel column corresponds to a main power signal access point, a plurality of the main power signal access points are located in a same column, and the main power signal access points are used for receiving a first power voltage.

2. The display panel as claimed in claim 1, wherein the data line is located between the non-shared pixel row and the shared pixel row adjacent to the non-shared pixel row.

3. The display panel as claimed in claim 2, wherein the data line is located in a middle position between the non-shared pixel row and the shared pixel row adjacent to the non-shared pixel row.

4. (canceled)

5. (canceled)

6. The display panel as claimed in claim 1, wherein each shared sub-pixel in the shared pixel column corresponds to a secondary power signal access point, a plurality of the secondary power signal access points are located in a same column, and the secondary power signal access points are used for receiving a second power voltage.

7. The display panel as claimed in claim 6, wherein the main power signal access point is connected to an anode of the non-shared sub-pixel by a first connecting line, and the secondary power signal access point is connected to an anode of the shared sub-pixel by a second connecting line.

8. The display panel as claimed in claim 1, wherein a total number of the scanning lines is a sum of a total number of the non-shared pixel columns and a total number of the shared pixel columns.

9. A display screen, comprising a display panel that comprises:
a non-shared pixel array consisting of a plurality of non-shared pixels, wherein the non-shared pixel array comprises a plurality of non-shared pixel columns and a plurality of non-shared pixel rows;
a shared pixel array consisting of a plurality of shared pixels, wherein the shared pixel array comprises a plurality of shared pixel columns and a plurality of shared pixel rows, the shared pixel columns are disposed between two adjacent non-shared pixel columns, and the shared pixel rows are disposed between two adjacent non-shared pixel rows;
a plurality of data lines, wherein the non-shared pixel row and the shared pixel column adjacent to the non-shared pixel row correspond to one data line; and
a plurality of scanning lines, wherein the non-shared pixel column and the shared pixel column respectively correspond to one scanning line;
wherein the non-shared pixel comprises two non-shared sub-pixels, each non-shared sub-pixel in the non-shared pixel column corresponds to a main power signal access point, a plurality of the main power signal access points are located in a same column, and the main power signal access points are used for receiving a first power voltage.

10. The display screen as claimed in claim 9, wherein the data line is located between the non-shared pixel row and the shared pixel row adjacent to the non-shared pixel row.

11. The display screen as claimed in claim 10, wherein the data line is located in a middle position between the non-shared pixel row and the shared pixel row adjacent to the non-shared pixel row.

12. (canceled)

13. (canceled)

14. The display screen as claimed in claim 9, wherein each shared sub-pixel in the shared pixel column corresponds to a secondary power signal access point, a plurality of the secondary power signal access points are located in a same column, and the secondary power signal access points are used for receiving a second power voltage.

15. The display screen as claimed in claim 14, wherein the main power signal access point is connected to an anode of the non-shared sub-pixel by a first connecting line, and the secondary power signal access point is connected to an anode of the shared sub-pixel by a second connecting line.

16. The display screen as claimed in claim 9, wherein a total number of the scanning lines is a sum of a total number of the non-shared pixel columns and a total number of the shared pixel columns.

17. An electronic device, comprising a display screen that comprises a display panel comprising:
a non-shared pixel array consisting of a plurality of non-shared pixels, wherein the non-shared pixel array comprises a plurality of non-shared pixel columns and a plurality of non-shared pixel rows;
a shared pixel array consisting of a plurality of shared pixels, wherein the shared pixel array comprises a plurality of shared pixel columns and a plurality of shared pixel rows, the shared pixel columns are disposed between two adjacent non-shared pixel columns, and the shared pixel rows are disposed between two adjacent non-shared pixel rows;
a plurality of data lines, wherein the non-shared pixel row and the shared pixel column adjacent to the non-shared pixel row correspond to one data line; and
a plurality of scanning lines, wherein the non-shared pixel column and the shared pixel column respectively correspond to one scanning line;
wherein the non-shared pixel comprises two non-shared sub-pixels, each non-shared sub-pixel in the non-shared pixel column corresponds to a main power signal access point, a plurality of the main power signal access points are located in a same column, and the main power signal access points are used for receiving a first power voltage.

18. The electronic device as claimed in claim 17, wherein the data line is located between the non-shared pixel row and the shared pixel row adjacent to the non-shared pixel row.

19. (canceled)

20. (canceled)

21. The display panel as claimed in claim 1, wherein a total number of the data lines is equal to a total number of the non-shared pixel rows, and a total number of the non-shared pixel rows is greater than or equal to a total number of the shared pixel rows.

22. The display screen as claimed in claim 9, wherein a total number of the data lines is equal to a total number of the non-shared pixel rows, and a total number of the non-shared pixel rows is greater than or equal to a total number of the shared pixel rows.

23. The electronic device as claimed in claim 17, wherein a total number of the data lines is equal to a total number of the non-shared pixel rows, and a total number of the non-shared pixel rows is greater than or equal to a total number of the shared pixel rows.
